(19) United States
(12) Patent Application Publication
(10) Pub. No.: US 2010/0000778 A1
(43) Pub. Date: Jan. 7, 2010

(54) PRINTED CIRCUIT BOARD

(75) Inventor: Ping Wang, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/205,151

(22) Filed: Sep. 5, 2008

(30) Foreign Application Priority Data
Jul. 3, 2008 (CN) 200820301435.X

(51) Int. Cl. H05K 1/11

(52) U.S. Cl. 174/266

(57) ABSTRACT

A printed circuit board (PCB) includes a top layer, a bottom layer, and reference layers between the top layer and the bottom layer. A via defined through the top layer, reference layers, and the bottom layer has only two pads at the reference layers.

### BACKGROUND

1. Technical Field

The present invention relates to PCB vias for high speed signals.

2. Description of Related Art

A typical printed circuit board (PCB) is designed to connect various electronic components to each other in a predetermined pattern. When a high-speed signal travels from one layer to another through a signal via, the return current path is interrupted because the return current must change reference planes, thereby inducing Electro Magnetic Interference and Signal Integrity problems. One solution to these problems is to place an additional decoupling capacitor adjacent to the signal via to provide a high-frequency current path between two planes for the return current. However, this adds additional inductance in the return path.

FIG. 2 is a schematic view of a typical PCB defining a ground via for high-speed signals that travel from layer to layer in the PCB. The ground via is drilled through a top layer, two reference ground layers, and a bottom layer of the PCB and has mounting pads at each layer. However, it is not uncommon for the mounting pads at the top and bottom layers to go unused, wasting space.

Therefore, a space-saving PCB defining vias without unused pad is desired to overcome the above-described shortcomings.

### BRIEF DESCRIPTION OF THE DRAWINGS

FIG. 1 is a schematic view of an embodiment of a PCB defining a ground via; and

FIG. 2 is a schematic view of a typical PCB defining a ground via.

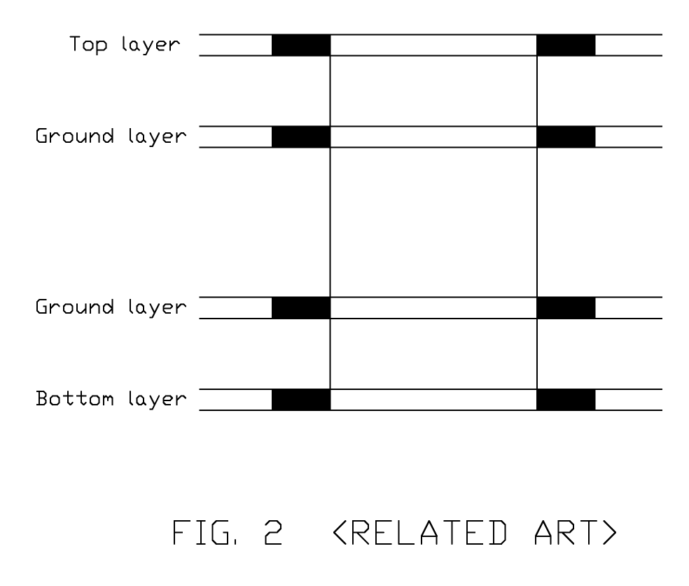

### DETAILED DESCRIPTION OF THE EMBODIMENTS

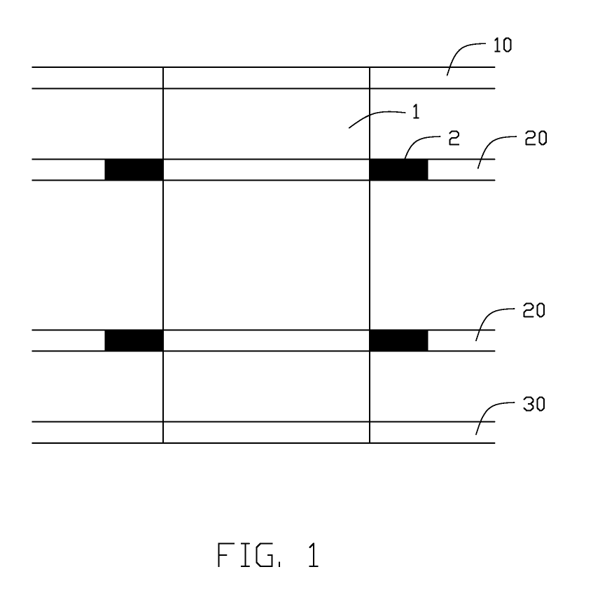

Referring to FIG. 1, an embodiment of a PCB (not labeled) includes a top layer 10, a bottom layer 30, and two ground layers 20 between the top layer 10 and the bottom layer 30. A via 1 is defined through the top layer 10, the ground layers 20, and the bottom layer 30. The via 1 has two pads 2 with each pad defined at each ground layer 20. For exemplary purposes only, a diameter of the via 1 is 14 mils, and an outer diameter of each of the pads 2 is 20 mils.

The PCB may be manufactured by drilling a 14 mil hole through the PCB along a central axis of the pads 2. An inner surface of the drill hole is coated with copper to form the via 1, which electronically connects the ground layers 20. A thickness of the copper is in a range of about 1 mil to about 2 mils. Thus, an inner diameter of the via 1, is approximately in a range of about 10 mils to about 12 mils.

In one embodiment, the via 1 is a ground return via defined in proximity to a signal via for high speed signals which travel from one layer to another in the PCB. The pads 2 at the ground layers 20 have connections with signal traces for the high speed signals. The via 1 has no connection with signal traces at the top layer 10 and the bottom layer 30 because there is no pad at either the top layer 10 or the bottom layer 30.

The PCB may be more compact because pads typically on the top layer 10 and the bottom layer 30 are omitted. The via 1 can perform as the return path of the high speed signals as they change from one layer to another. The via 1 performs better than the typical via when the frequency of the high speed signals exceed 10 GHZ.

In other embodiments, the PCB may include two power layers instead of two ground layers.

It is to be understood, however, that even though numerous characteristics and advantages of the present embodiments have been set forth in the foregoing description, together with details of the structure and function of the invention, the disclosure is illustrative only, and changes may be made in detail, especially in matters of shape, size, and arrangement of parts within the principles of the embodiments to the full extent indicated by the broad general meaning of the terms in which the appended claims are expressed.

What is claimed is:

1. A printed circuit board (PCB), comprising:
a first layer;
a second layer; and
a via defined through the first layer and the second layer, the via comprising a pad at one of the first layer and the second layer.

2. The PCB of claim 1, wherein the first layer is a top layer, and the second layer is a ground layer.

3. The PCB of claim 2, wherein the pad of the via is defined at the ground layer.

4. The PCB of claim 3, further comprising a bottom layer.

5. The PCB of claim 4, further comprising another ground layer, wherein the via further comprises another pad at the bottom layer.

6. The PCB of claim 5, wherein the via is adjacent to a signal via.

7. A printed circuit board (PCB), comprising:
a top layer;
a bottom layer;
two reference layers positioned between the top layer and the bottom layer; and
a via defined through the top layer, the two reference layers, and the bottom layer, the via comprising a pads at each reference layer.

8. The PCB of claim 7, wherein the via is a ground via adjacent to a signal via.

9. The PCB of claim 8, wherein each reference layer is a ground layer.

10. The PCB of claim 7, wherein the via is a power via adjacent to a signal via.

11. The PCB of claim 10, wherein each reference layers is a power layer.
